(19) United States
(12) Patent Application Publication
(10) Pub. No.: US 2026/0221876 A1
(43) Pub. Date: Jul. 30, 2026

(54) CURRENT MANAGEMENT CIRCUIT, SYSTEM AND METHOD WITH CURRENT CLAMPING FOR IMPROVING PERFORMANCE, REDUCING POWER DELIVERY NETWORK INVESTMENT AND PROVIDING PROTECTION

(71) Applicant: MediaTek Singapore Pte. Ltd., Singapore (SG)

(72) Inventors: Yu-Hsing Shen, Hsinchu City (TW); Lin-Chien Chen, Hsinchu City (TW); Hsin-Chen Chen, San Jose, CA (US)

(73) Assignee: MediaTek Singapore Pte. Ltd., Singapore (SG)

(21) Appl. No.: 19/578,937

(22) Filed: Mar. 26, 2026

Related U.S. Application Data
(63) Continuation-in-part of application No. 19/260,335, filed on Jul. 4, 2025.
Application No. 19/260,335 is a continuation-in-part of application No. 18/271,847, filed on Sep. 9, 2022, now Pat. No. 12,375,088.
(60) Provisional application No. 63/242,070, filed on Sep. 9, 2021.

(51) Int. Cl. H02M 3/155

(52) U.S. Cl. CPC H02M 3/155

(57) ABSTRACT

A current management method controls a circuit including a processing circuit consuming a load current and a voltage-controlled oscillator with terminals coupled to a power management integrated circuit and the processing circuit. The method includes detecting whether the load current exceeds a current threshold by the power management integrated circuit, clamping an output current substantially to a maximum output current when the threshold is exceeded, sensing an output voltage drop by the voltage-controlled oscillator, and adjusting an output signal to reduce a frequency. The current threshold is less than or equal to the maximum output current. This achieves closed-loop control preventing system instability.

### CROSS REFERENCE TO RELATED APPLICATION

This application is a continuation-in-part of U.S. Application No. 19/260,335, filed on July 4th, 2025, which is a continuation-in-part of U.S. Application No. 18/271,847, filed on July 11th, 2023, now U.S. Patent No. 12,375,088 B2. The contents of these applications are incorporated herein by reference.

### BACKGROUND

With the continued advancement of electronic devices, power management has become increasingly critical. Effective power management must address multiple challenges, including system stability, circuit protection, device performance, power efficiency, and resource optimization. Achieving these objectives simultaneously remains difficult.

Existing solutions often require extensive hardware and complex control procedures, resulting in increased circuit complexity without achieving satisfactory performance. Improved power management solutions are needed.

### SUMMARY

An embodiment provides a current management circuit. The current management circuit includes a processing circuit and a voltage-controlled oscillator. The voltage-controlled oscillator includes a first terminal and a second terminal. The first terminal is coupled to a power management integrated circuit to receive an output voltage. The second terminal is coupled to the processing circuit and is used to output an output signal to adjust a frequency of the processing circuit. The voltage-controlled oscillator senses the output voltage through the first terminal. When a load current of the processing circuit exceeds a current threshold, the power management integrated circuit clamps an output current substantially to a maximum output current of the power management integrated circuit, reducing the output voltage, and causing the voltage-controlled oscillator to sense a drop in the output voltage to reduce the frequency. The current threshold is less than or equal to the maximum output current.

An embodiment provides a current management system. The current management system includes a power management integrated circuit, a processing circuit, and a voltage-controlled oscillator. The power management integrated circuit is used to provide an output voltage and an output current. The voltage-controlled oscillator includes a first terminal and a second terminal. The first terminal is coupled to the power management integrated circuit to receive the output voltage. The second terminal is coupled to the processing circuit and is used to output a signal to adjust a frequency of the processing circuit. The voltage-controlled oscillator senses the output voltage through the first terminal. When a load current of the processing circuit exceeds a current threshold, the power management integrated circuit clamps the output current substantially to a maximum output current of the power management integrated circuit, reducing the output voltage, and causing the voltage-controlled oscillator to sense a drop in the output voltage to reduce the frequency. The current threshold is less than or equal to the maximum output current.

An embodiment provides a current management method for controlling a current management circuit. The current management circuit includes a processing circuit and a voltage-controlled oscillator. The processing circuit consumes a load current. The voltage-controlled oscillator includes a first terminal and a second terminal. The first terminal is coupled to a power management integrated circuit to receive an output voltage. The second terminal is coupled to the processing circuit and is used to output an output signal to adjust a frequency of the processing circuit. The current management method includes detecting whether the load current exceeds a current threshold by the power management integrated circuit; clamping an output current to substantially a maximum output current of the power management integrated circuit in response to detecting that the load current exceeds the current threshold by the power management integrated circuit; sensing a drop in the output voltage by the voltage-controlled oscillator; and adjusting the output signal to reduce the frequency by the voltage-controlled oscillator. The current threshold is less than or equal to the maximum output current.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a current management circuit coupled to a power management integrated circuit according to an embodiment.

FIG. 2 illustrates a flowchart of a current management method for controlling the current management circuit according to an embodiment.

FIG. 3 illustrates a waveform diagram of load current over time according to an embodiment.

FIG. 4 illustrates a waveform diagram of output voltage over time according to an embodiment.

FIG. 5 illustrates a waveform diagram of frequency over time according to an embodiment.

### DETAILED DESCRIPTION

In this disclosure, when A is coupled to B, it indicates that A and B may be coupled through physical connections. The coupling between A and B may be direct or indirect through intermediate components. When X is linked to Y, it indicates that X and Y may be linked through wired, wireless, or a combination of wired and wireless means. The link between X and Y may be a hardware link or a software link, and data transmission may occur between X and Y. When "and/or" is used to combine multiple elements, it indicates one element or any combination of the multiple elements. For example, "C, D and/or E" means C, D, E, C and D, D and E, C and E, and C, D and E. In this disclosure, when referring to clamping a current, it indicates limiting and maintaining the current at a predetermined value or within a predetermined range. In this disclosure, when A is referred to as substantially B, it indicates that the difference between A and B may be less than 10%, 5%, or 1% of B.

Effective power management must address multiple challenges, including system stability, circuit protection, device performance, power efficiency, and resource optimization. Achieving these objectives simultaneously remains difficult. In systems with limited power delivery network (PDN) investment, system stability becomes challenging when load current exceeds the maximum current capability of the power management integrated circuit (PMIC). Higher maximum current enables faster execution speeds in processing circuits but requires more capable PDN infrastructure. When peak current demand cannot be met, the PMIC shuts down for self-protection, causing system instability. Processing circuits deployed in various applications often exhibit unpredictable peak current demands. To accommodate such uncertain conditions, PDNs are typically designed with additional margin, resulting in unnecessary resource investment and increased cost.

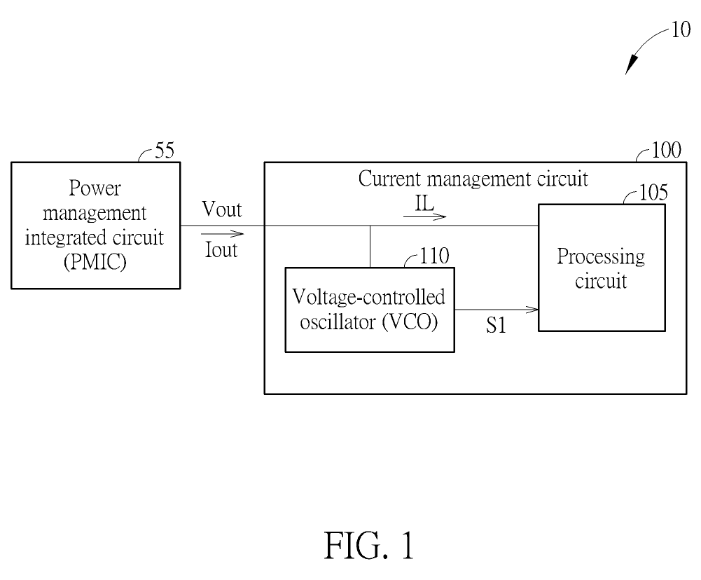

FIG. 1 illustrates a current management circuit 100 coupled to a power management integrated circuit 55 according to an embodiment. The current management circuit 100 includes a processing circuit 105 and a voltage-controlled oscillator (VCO) 110. The voltage-controlled oscillator 110 includes a first terminal and a second terminal. The first terminal may be coupled to the power management integrated circuit 55 to receive an output voltage Vout. The second terminal may be coupled to the processing circuit 105 and may be used to output an output signal S1 to adjust a frequency of the processing circuit 105. The voltage-controlled oscillator 110 may sense the output voltage Vout through the first terminal.

The load current IL may be the current drawn by the processing circuit 105 during operation. When the load current IL of the processing circuit 105 exceeds a current threshold (denoted as Ith), the power management integrated circuit 55 may clamp the output current Iout substantially to a maximum output current (denoted as Imax) of the power management integrated circuit 55. This clamping reduces the output voltage Vout, causing the voltage-controlled oscillator 110 to sense the drop in the output voltage Vout and reduce the frequency. The current threshold Ith may be less than or equal to the maximum output current Imax, that is, Ith ≤ Imax.

When the load current IL exceeds the current threshold Ith, it indicates that the processing circuit 105 is demanding more current than the threshold level, potentially causing the power management integrated circuit 55 to enter over-current protection or shut down. Therefore, the power management integrated circuit 55 may limit and clamp the output current Iout to substantially maintain it at the maximum output current Imax. This protects the power management integrated circuit 55 from damage and prevents system shutdown. Subsequently, because the output current Iout is limited, the output voltage Vout decreases, causing the frequency to decrease (controlled through the output signal S1), which in turn reduces the load current IL below the current threshold Ith. Accordingly, a closed-loop control is achieved to avoid unwanted system instability or shutdown of the power management integrated circuit 55.

The current management circuit 100 may be applied in various applications according to requirements. For example, the current management circuit 100 may be applied in electronic devices such as mobile phones and tablet computers. In such cases, the power management integrated circuit 55 may be an external device. The current management circuit 100 may be integrated in a system on chip (SoC) and disposed on a printed circuit board, a flexible circuit board, a field-programmable gate array (FPGA), a package structure, or other suitable structures.

Alternatively, a current management system 10 may be used, where the current management system 10 may include the power management integrated circuit 55, the voltage-controlled oscillator 110, and the processing circuit 105. An appropriate architecture may be selected based on requirements.

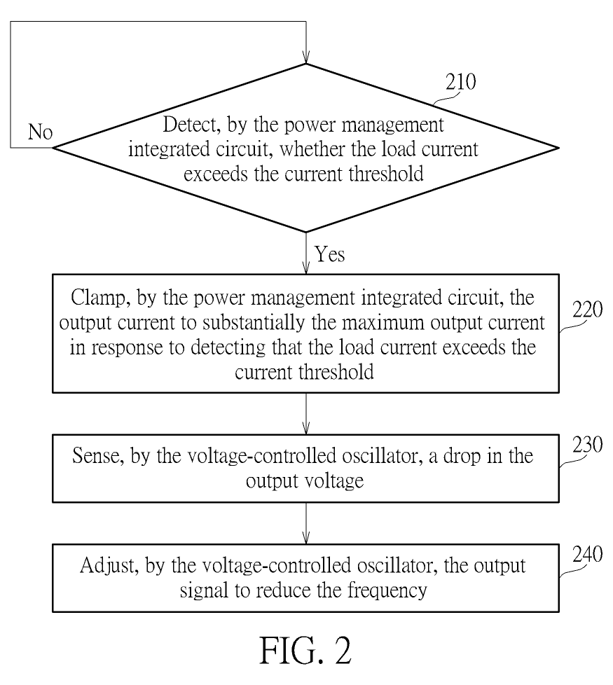

FIG. 2 illustrates a flowchart of a current management method 200 for controlling the current management circuit 100 according to an embodiment. The method 200 may include the following steps.

Step 210: detect, by the power management integrated circuit 55, whether the load current IL exceeds the current threshold Ith; if yes, proceed to Step 220; if no, return to Step 210;

Step 220: clamp, by the power management integrated circuit 55, the output current Iout to substantially the maximum output current Imax of the power management integrated circuit 55 in response to detecting that the load current IL exceeds the current threshold Ith;

Step 230: sense, by the voltage-controlled oscillator 110, a drop in the output voltage Vout; and

Step 240: adjust, by the voltage-controlled oscillator 110, the output signal S1 to reduce the frequency.

According to FIG. 1 and FIG. 2, through the determination in Step 210 and the operations in Steps 220 to 240, the aforementioned system instability or shutdown issues may be avoided without requiring substantial additional circuitry, effectively achieving automatic control to ensure efficiency and safety. Since the determination step in FIG. 2 is Step 210, two separate determination steps for determining whether the current is excessive and whether the voltage is excessive are not necessary.

In Step 220, the output current Iout may be substantially clamped to the maximum output current Imax. To account for reasonable current variations, the power management integrated circuit 55 may clamp the output current Iout to be within ±10% of the maximum output current Imax.

Regarding the current threshold Ith, the current threshold Ith may be configurable based on requirements. The current threshold Ith may be less than or equal to the maximum output current Imax, that is, Ith ≤ Imax. The current threshold Ith may be between 50% and 100% of the maximum output current Imax. When the load current IL exceeds the current threshold Ith, over-current conditions may occur. If the current threshold Ith is set to 100% of the maximum output current Imax (i.e., Ith = Imax), transient spikes in the load current IL above the maximum output current Imax may trigger Step 210, initiating the clamping operation. If this trigger condition proves unsuitable due to system factors, the current threshold Ith may be reduced. The current threshold Ith may be adjusted based on experimental results and circuit design requirements.

In this disclosure, the processing circuit 105 may include a member selected from a group including a central processing unit (CPU), a graphics processing unit (GPU), a neural processing unit (NPU), a tensor processing unit (TPU), an application processor (AP), a digital signal processor (DSP), and a microcontroller unit (MCU). However, this is merely exemplary. The processing circuit 105 may be any suitable circuit that can receive the output voltage Vout and the output current Iout from the power management integrated circuit 55 and can have its frequency set by the voltage-controlled oscillator 110.

The processing circuit 105 and the voltage-controlled oscillator 110 may be integrated in a chip, such as a system on chip (SoC). However, this is merely exemplary. If the voltage-controlled oscillator 110 and the processing circuit 105 are located on different chips and coupled through conductive paths or package structures, this also falls within the scope of embodiments.

Regarding the voltage-controlled oscillator 110, it may include a member selected from a group comprising a ring oscillator, a relaxation oscillator, an inductor-capacitor (LC) oscillator, a crystal oscillator, a digitally controlled oscillator, and a resistor-capacitor (RC) oscillator.

The power management integrated circuit 55 may include a member selected from a group including a direct-current-to-direct-current (DC-DC) converter, a switching regulator, a linear regulator, a buck converter, a boost converter, a buck-boost converter, a low-dropout regulator (LDO), a charge pump, a step-down converter, and a step-up converter. Other suitable converters or regulators may also be used for the power management integrated circuit 55.

Regarding the voltage-controlled oscillator 110 and the frequency corresponding to the output signal S1, the following applies. The voltage-controlled oscillator 110 may determine the frequency based on the output voltage Vout. The frequency may be positively correlated with the output voltage Vout. That is, when the output voltage Vout increases, the frequency may increase, and when the output voltage Vout decreases, the frequency may decrease.

In an embodiment, the frequency may be substantially linearly correlated with the output voltage Vout within a predetermined voltage range. For example, the frequency may be linearly correlated with the output voltage Vout within a full operating voltage range.

Regarding the voltage-controlled oscillator 110 providing the output signal S1 to determine the frequency of the processing circuit 105, the output signal S1 may be a clock signal with a frequency, or S1 may contain frequency-related information. The output signal S1 may include a member selected from a group including a clock signal, a periodic signal, a pulse signal, a square wave signal, a sinusoidal signal, a digital control signal, and a frequency control word (FCW). Other signal formats that can be used to adjust the frequency of the processing circuit 105 also fall within the scope of embodiments.

The load current IL may be positively correlated with the frequency of the processing circuit 105. Therefore, after Step 240, the load current IL may decrease. Accordingly, the over-current condition in Step 210 may be automatically addressed, thereby achieving closed-loop control.

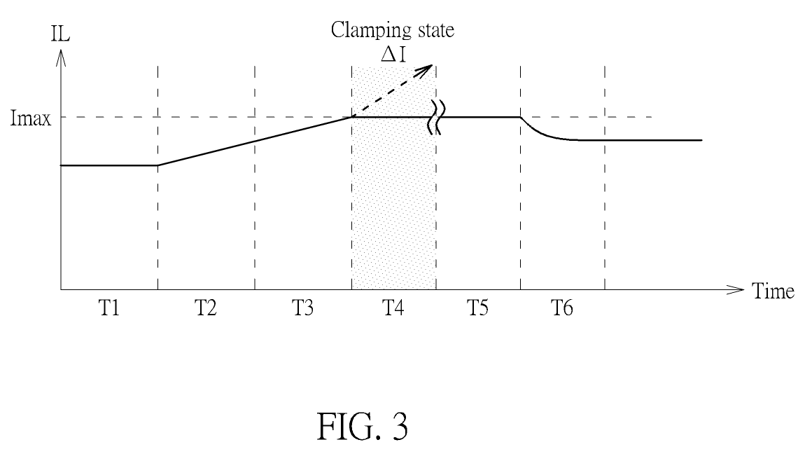

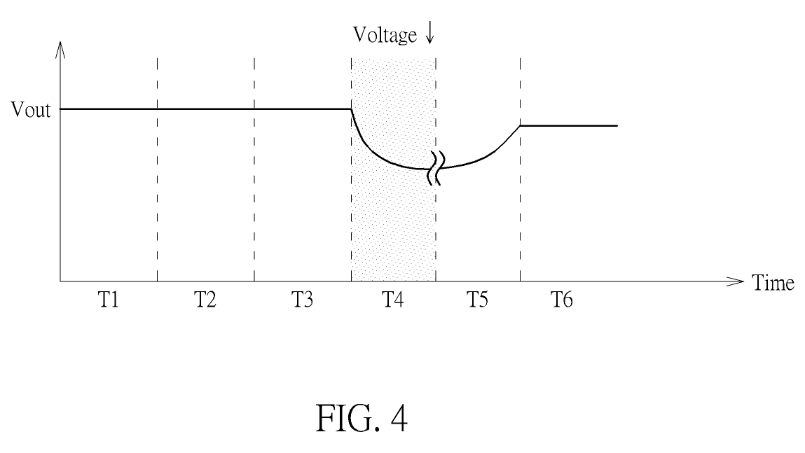

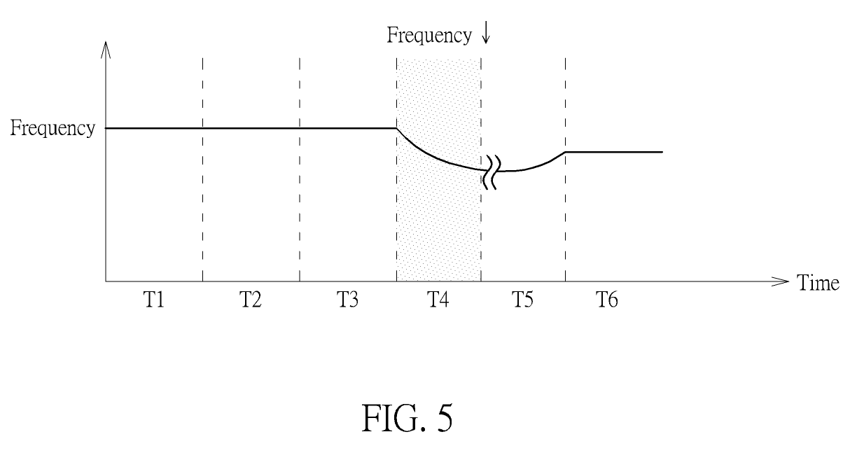

FIG. 3, FIG. 4, and FIG. 5 illustrate waveform diagrams of an example for executing the method of FIG. 2.

In FIG. 3 to FIG. 5, the horizontal axis represents time, which in this example may be divided into six time periods T1 to T6. The vertical axis of FIG. 3 represents the load current IL. The vertical axis of FIG. 4 represents the output voltage Vout. The vertical axis of FIG. 5 represents the frequency of the processing circuit 105. As shown in FIG. 3, before time period T4, the load current IL does not exceed the current threshold Ith. In time period T4, the load current IL reaches the current threshold Ith and is thus clamped at the maximum output current Imax. In this example, the current threshold Ith is close to the maximum output current Imax. FIG. 3 shows a current difference ΔI, indicating the current difference between the load current IL and the current threshold Ith if the load current IL were not clamped. However, since the load current IL is clamped, the current difference ΔI is merely illustrative and does not actually occur. Because the load current IL reaches the current threshold Ith, as shown in FIG. 4, during time period T4, the output voltage Vout decreases, producing a voltage drop. Due to the voltage drop in FIG. 4, the voltage-controlled oscillator 110 reduces the frequency through the output signal S1. As shown in FIG. 5, during time period T4, the frequency decreases. Because the frequency decreases during time period T4 in FIG. 5, as shown in FIG. 3, the load current IL may decrease in time period T6. Hence, as shown in FIG. 4 and FIG. 5, during time period T6, the output voltage Vout may recover and the frequency may increase.

The increase in the load current IL in FIG. 3 and its clamping lead to changes in the output voltage Vout in FIG. 4. The changes in the output voltage Vout in FIG. 4 lead to frequency changes in FIG. 5. The frequency changes in FIG. 5 in turn lead to changes in the load current IL in FIG. 3, thereby achieving closed-loop control. FIG. 3 to FIG. 5 are merely exemplary, and other suitable waveforms also fall within the scope of embodiments.

In summary, the current management circuit 100, current management system 10, and current management method 200 can achieve effective power management, address over-current conditions and system instability, improve performance, reduce energy consumption, reduce the need for additional circuitry, and provide compatibility with various voltage-controlled oscillators and power management integrated circuits. Accordingly, these embodiments enhance system stability, circuit protection, device performance, power efficiency, and resource optimization.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A current management circuit comprising:
a processing circuit; and
a voltage-controlled oscillator comprising:
a first terminal coupled to a power management integrated circuit to receive an output voltage; and
a second terminal coupled to the processing circuit and configured to output an output signal to adjust a frequency of the processing circuit;
wherein the voltage-controlled oscillator senses the output voltage through the first terminal;
when a load current of the processing circuit exceeds a current threshold, the power management integrated circuit clamps an output current substantially to a maximum output current of the power management integrated circuit, reducing the output voltage, and causing the voltage-controlled oscillator to sense a drop in the output voltage to reduce the frequency; and
wherein the current threshold is less than or equal to the maximum output current.

2. The current management circuit of claim 1, wherein the power management integrated circuit clamps the output current to be within ±10% of the maximum output current.

3. The current management circuit of claim 1, wherein the current threshold is between 50% and 100% of the maximum output current.

4. The current management circuit of claim 1, wherein the processing circuit comprises a member selected from a group comprising a central processing unit (CPU), a graphics processing unit (GPU), a neural processing unit (NPU), a tensor processing unit (TPU), an application processor (AP), a digital signal processor (DSP), and a microcontroller unit (MCU).

5. The current management circuit of claim 1, wherein the processing circuit and the voltage-controlled oscillator are integrated in a system on chip (SoC).

6. The current management circuit of claim 1, wherein the voltage-controlled oscillator comprises a member selected from a group comprising a ring oscillator, a relaxation oscillator, an inductor-capacitor (LC) oscillator, a crystal oscillator, a digitally controlled oscillator, and a resistor-capacitor (RC) oscillator.

7. The current management circuit of claim 1, wherein the voltage-controlled oscillator determines the frequency based on the output voltage.

8. The current management circuit of claim 7, wherein the frequency is positively correlated with the output voltage.

9. The current management circuit of claim 7, wherein the frequency is substantially linearly correlated with the output voltage.

10. The current management circuit of claim 1, wherein the output signal outputted by the voltage-controlled oscillator comprises a member selected from a group comprising a clock signal, a periodic signal, a pulse signal, a square wave signal, a sinusoidal signal, a digital control signal, and a frequency control word (FCW).

11. The current management circuit of claim 1, wherein the load current is positively correlated with the frequency.

12. The current management circuit of claim 1, wherein the power management integrated circuit comprises a member selected from a group comprising a direct-current-to-direct-current (DC-DC) converter, a switching regulator, a linear regulator, a buck converter, a boost converter, a buck-boost converter, a low-dropout regulator (LDO), a charge pump, a step-down converter, and a step-up converter.

13. A current management system comprising:
a power management integrated circuit configured to provide an output voltage and an output current;
a processing circuit; and
a voltage-controlled oscillator comprising:
a first terminal coupled to the power management integrated circuit to receive the output voltage; and
a second terminal coupled to the processing circuit and configured to output a signal to adjust a frequency of the processing circuit;
wherein the voltage-controlled oscillator senses the output voltage through the first terminal;
when a load current of the processing circuit exceeds a current threshold, the power management integrated circuit clamps the output current substantially to a maximum output current of the power management integrated circuit, reducing the output voltage, and causing the voltage-controlled oscillator to sense a drop in the output voltage to reduce the frequency; and
the current threshold is less than or equal to the maximum output current.

14. A current management method for controlling a current management circuit, the current management circuit comprising a processing circuit and a voltage-controlled oscillator, the processing circuit consuming a load current, the voltage-controlled oscillator comprising a first terminal and a second terminal, the first terminal being coupled to a power management integrated circuit to receive an output voltage, the second terminal being coupled to the processing circuit to output an output signal to adjust a frequency to the processing circuit, the current management method comprising:
detecting, by the power management integrated circuit, whether the load current exceeds a current threshold;
clamping, by the power management integrated circuit, an output current to substantially a maximum output current of the power management integrated circuit in response to detecting that the load current exceeds the current threshold;
sensing, by the voltage-controlled oscillator, a drop in the output voltage; and
adjusting, by the voltage-controlled oscillator, the output signal to reduce the frequency;
wherein the current threshold is less than or equal to the maximum output current.
